(19) United States
(12) Patent Application Publication
(10) Pub. No.: US 2012/0306565 A1
(43) Pub. Date: Dec. 6, 2012

(54) PROJECTED CAPACITIVE TOUCH PANEL WITH IMPEDANCE ADJUSTMENT STRUCTURE

(75) Inventor: Jane Hsu, Taoyuan County (TW)

(73) Assignee: DerLead Investment Ltd., Taipei (TW)

(21) Appl. No.: 13/187,919

(22) Filed: Jul. 21, 2011

(30) Foreign Application Priority Data
Jun. 1, 2011 (TW) 100209927

(51) Int. Cl. H03K 17/96

(52) U.S. Cl. 327/517

(57) ABSTRACT

A projected capacitive touch panel with impedance adjustment structure has an X-axis sensing layer and a Y-axis sensing layer. The X-axis sensing layer has multiple X-axis electrode strings. Each X-axis electrode string has multiple X-axis electrodes connected in series. The Y-axis sensing layer has multiple Y-axis electrode strings. Each Y-axis electrode string has multiple Y-axis electrodes in series. The Y-axis electrodes and the X-axis electrode are arranged alternately to form a coupling capacitor between an X-axis electrode and a Y-axis electrode. At least one gap is formed on part of or all the X, Y axis electrodes to reduce the electrode area and the impedance of the electrodes, thereby enhancing the sensing sensitivity and being beneficial to enlarge the size of the touch panel.

### BACKGROUND OF THE INVENTION

1. Field of the Invention

The present invention relates to a projected capacitive touch panel, and more particular to a projected capacitive touch panel with impedance adjustment structure.

2. Description of Related Art

A basic structure of a conventional projected capacitive touch panel as shown in FIG. 5 comprises an X-axis sensing layer 80 and a Y-axis sensing layer 90. The X-axis sensing layer 80 comprises multiple X-axis electrode strings arranged horizontally. Each of the X-axis electrode strings is composed of multiple X-axis electrodes 81 in rhombic shape. Each X-axis electrode string is respectively connected to an X-axis driving line 82.

The Y-axis sensing layer 90 has multiple Y-axis electrode strings arranged lengthwise. Each of the Y-axis electrode strings is composed of multiple Y-axis electrodes 91 in rhombic shape. Each Y-axis electrode string is respectively connected to a Y-axis driving line 92.

The Y-axis electrodes 91 and the X-axis electrodes 81 are alternately arranged and electrically isolated from each other. An X-axis electrode 81 and a neighboring Y-axis electrode 91 form a coupling capacitor.

The X-, Y-axis sensing layers 80, 90 can be formed on a substrate. The X-, Y-axis driving lines 82, 92 extend to one side of the substrate along the edge of the substrate to connect to a connecting port. A controller is connected to the connecting port and detects the capacitance changes between the neighboring electrodes. With regard to the projected capacitive touch panel, the coordination requirement between the sensing interface (X-, Y-axis sensing layers 80, 90) and the controller is relative high. Because the X-, Y-axis driving lines 82, 92 are arranged along the edge of the substrate, the lengths of each X-, Y-axis driving lines 82, 92 are different. The resistance values of the X-, Y-axis driving lines 82 92 are proportional to the lengths of the X-, Y-axis driving lines 82 92. As the size of the touch panel increases, the resistance values of the driving lines will become higher because of the long X-, Y-axis driving lines 82, 92. Therefore, the sensitivity of the controller may be affected to cause an error of identification.

FIG. 6 is a cross-sectional view of the projected capacitive touch panel. The X-axis electrodes 61 and the Y-axis electrodes 62 are alternately arranged on the substrate 60. A transparent panel 63 is mounted on the substrate 60. The coupling capacitors (Cp) are formed between the X-axis electrode 61 and the Y-axis electrode 62.

With reference to FIG. 7, because the finger of a user or any conductive object is conductive, a new capacitor (Cf) is generated when the finger or the conductive object touches the transparent panel 63 and approaches the X-, Y-axis electrodes 61,62. Therefore, when the controller scans the X-, Y-axis electrodes 61, 62 through the X-, Y-axis driving lines, a capacitance of the summation of Cp and Cf is detected, thereby determining the position being touched. According to the foregoing approach, the sensitivity of the touch panel can be increased by decreasing the coupled capacitor (Cp) between the neighboring X, Y axis electrodes 61, 62.

### SUMMARY OF THE INVENTION

The main objective of the invention is to provide a projected capacitive touch panel with impedance adjustment structure. Part of or all the electrodes of the touch panel are reduced in area to decrease coupling capacitance between the adjacent electrodes, thereby enhancing the sensing sensitivity of the touch panel and allowing the touch panel to be enlarged in size.

To accomplish the objective, the touch panel has an X-axis sensing layer and a Y-axis sensing layer.

The X-axis sensing layer has multiple X-axis electrode strings; multiple X-axis driving lines, each of the X-axis driving lines connected to one end of one of the X-axis electrode strings, wherein the X-axis electrode strings comprise multiple X-axis electrodes connected in series; and at least one first gap formed around at least one of the X-axis electrodes.

The Y-axis sensing layer has multiple Y-axis electrode strings; multiple Y-axis driving lines, each of the Y-axis driving lines connected to one end of one of the Y-axis electrode strings, wherein the Y-axis electrode strings comprise multiple Y-axis electrodes in series, wherein the Y-axis electrodes and the X-axis electrodes are arranged alternately; and at least one second gap formed around at least one of the Y-axis electrodes.

Because the first and second gaps are formed around the X-axis electrode and Y-axis electrode of the touch panel, the area of the electrode is reduced. A coupling capacitance between an X-axis electrode and a Y-axis electrode is proportional to the area of the X-, Y-axis electrodes. When the area of the X-, Y-axis electrodes is reduced, the coupling capacitance is decreased relatively.

In the case that the coupling capacitance has been decreased, the sensitivity to the change of capacitance is increased when a finger or any conductive object approaches the touch panel to induce a new capacitor. Because the sensitivity is capable of being increased in accordance with the invention, a problem of low sensitivity of the X-, Y-axis electrode strings far from a connecting port is overcome. Therefore, the touch panel is able to be enlarged in size and still maintains satisfactory sensitivity.

Furthermore, because each gap is formed with an open end, the position and size of the gaps on the X-,Y-axis electrodes are easily defined when forming the X-, Y-axis electrodes through etching process. Furthermore, the area of the X-, Y-axis electrodes is easily controlled to adjust the capacitance between the electrodes.

### BRIEF DESCRIPTION OF THE DRAWINGS

FIG. 1 is a planar view of X-, Y-axis sensing layers of a first preferred embodiment of the invention;

FIG. 2A to FIG. 2D are planar views of the different gaps formed on the X-axis electrode in the shape and size of the touch panel of FIG. 1;

FIG. 3 is a planar view of X-, Y-axis sensing layers of a second preferred embodiment of the invention;

FIG. 4 is planar view of a connecting port mounted on a substrate and part of the enlarged X-, Y-axis electrodes of the invention;

FIG. 5 is a planar view of a conventional projected capacitive touch panel;

FIG. 6 is a schematic view of a coupled capacitor formed between the X-axis electrode and the Y-axis electrode of the touch panel of FIG. 4; and

FIG. 7 is a schematic view showing a coupling capacitor formed between the X-axis electrode and the Y-axis electrode and showing a capacitor when a finger touches the touch panel of FIG. 4.

### DETAILED DESCRIPTION OF THE PREFERRED EMBODIMENT

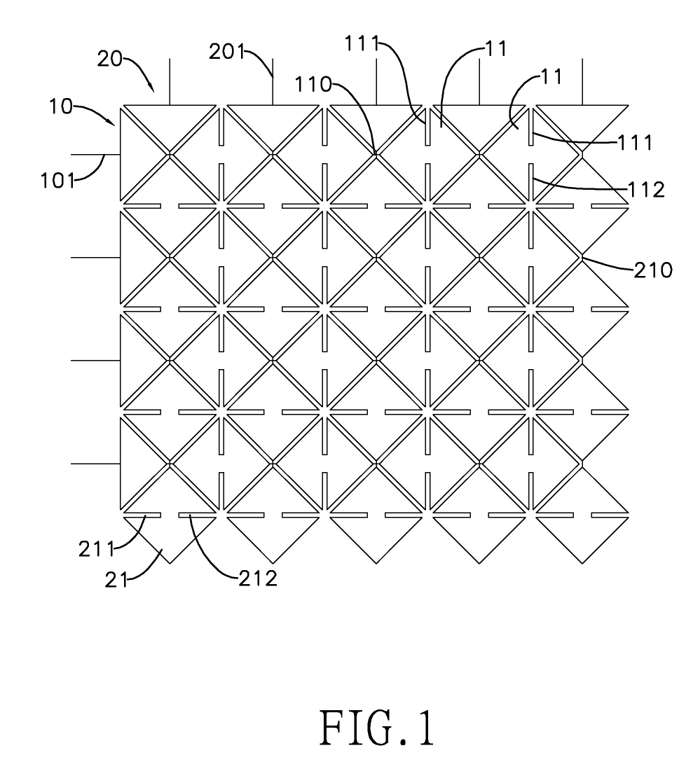

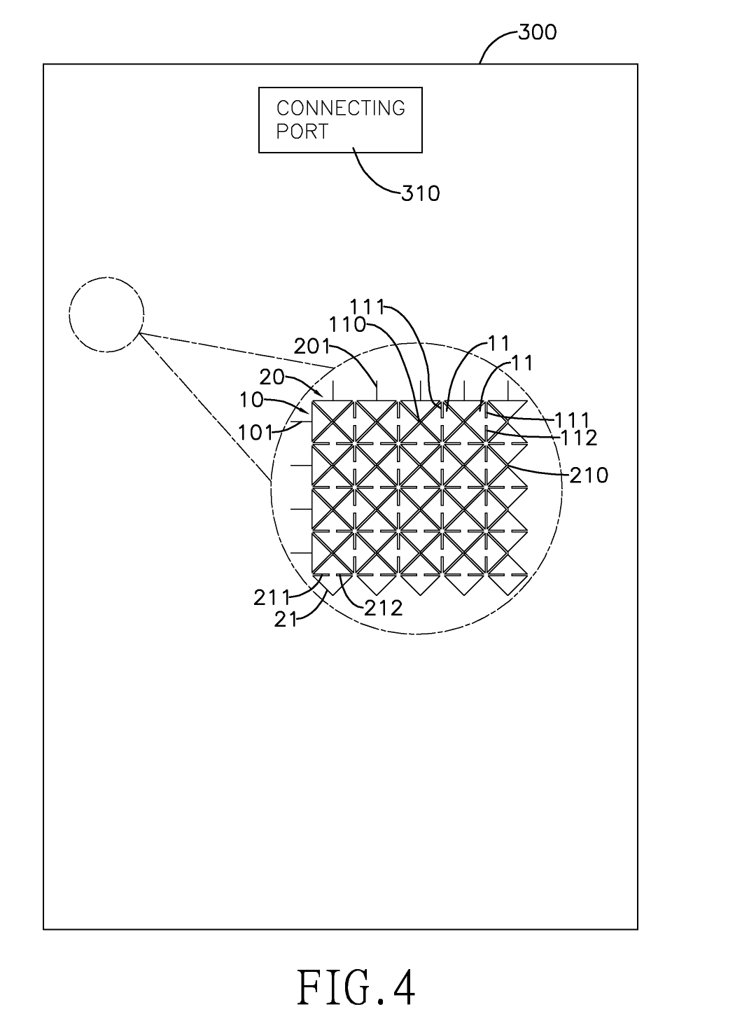

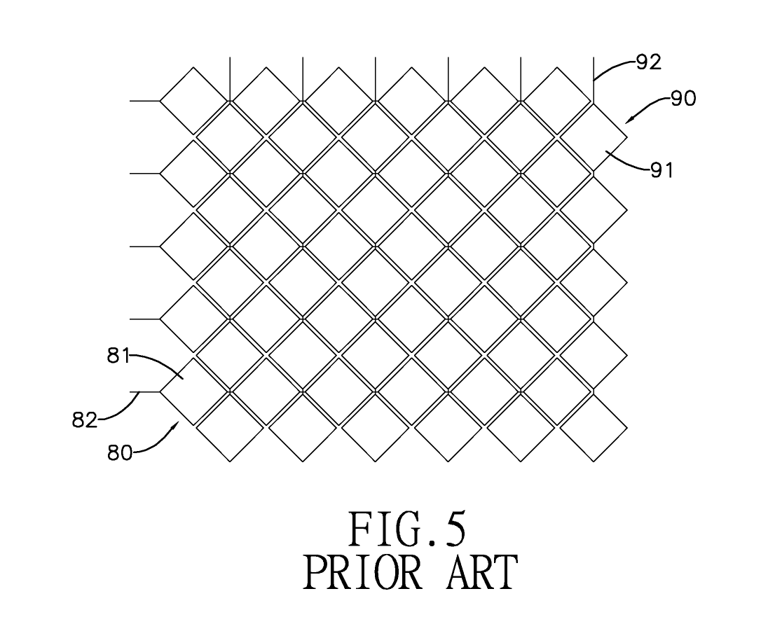

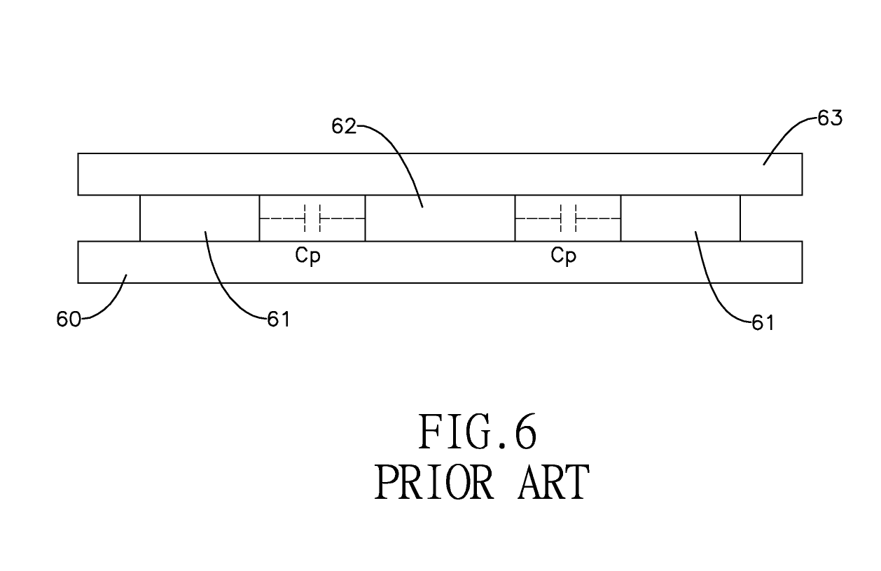

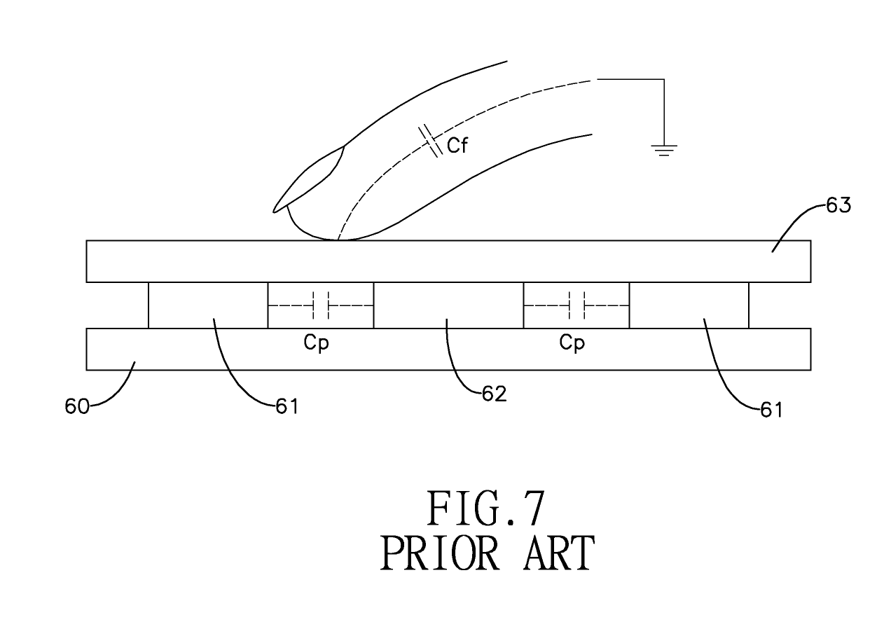

With reference to FIGS. 1 and 4, a preferred embodiment of a projected capacitive touch panel with impedance adjustment structure has an X-axis sensing layer and a Y-axis sensing layer. The X-axis sensing layer and the Y-axis sensing layer can be formed on a substrate 300.

The X-axis sensing layer has multiple X-axis electrode strings 10. One end of each X-axis electrode string 10 is connected to an X-axis driving line 101 formed on the substrate 300. Each X-axis electrode string 10 is composed of multiple X-axis electrodes 11 connected in series. At least one gap 111, 112 is formed on at least one X-axis electrode 11 of at least one X-axis electrode string 10. The gaps 111, 112 are formed around the X-axis electrode 11.

In more detail, each X-axis electrode 11 is in rhombic shape with a right vertex, a left vertex, a top vertex and a bottom vertex. The right and left vertices of the X-axis electrodes 11 are respectively connected to an adjacent X-axis electrode 11 by an X-axis connecting bridge 110. In the embodiment, the gaps 111, 112 are respectively formed on the top and bottom vertices of the X-axis electrode 11. The shapes of the gaps 111, 112 can be regular or irregular. Because the gaps 111, 112 on the X-axis electrode 11 are formed around the X-axis electrode 11 with an open end, the location and the size of the gaps 111, 112 can be more easily defined during the manufacturing processes of the X-axis electrodes 11, such as during the patterning step and the etching step, and the area and the resistance of the X-axis electrode 11 are precisely controlled.

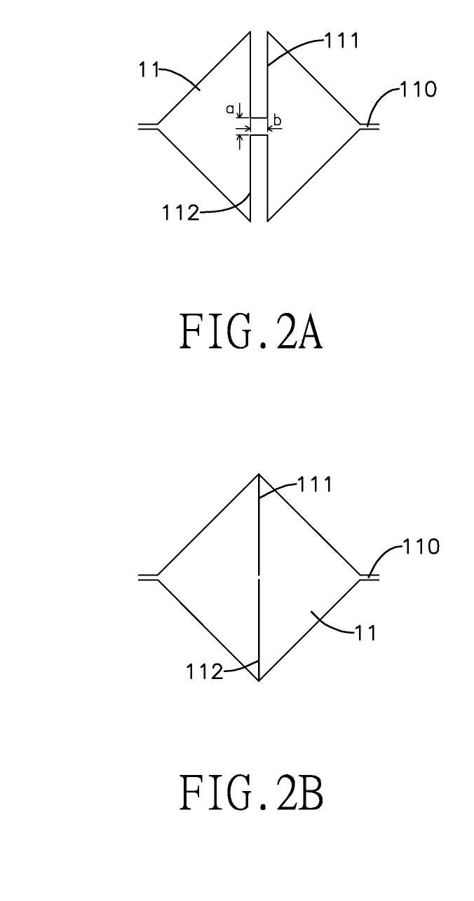

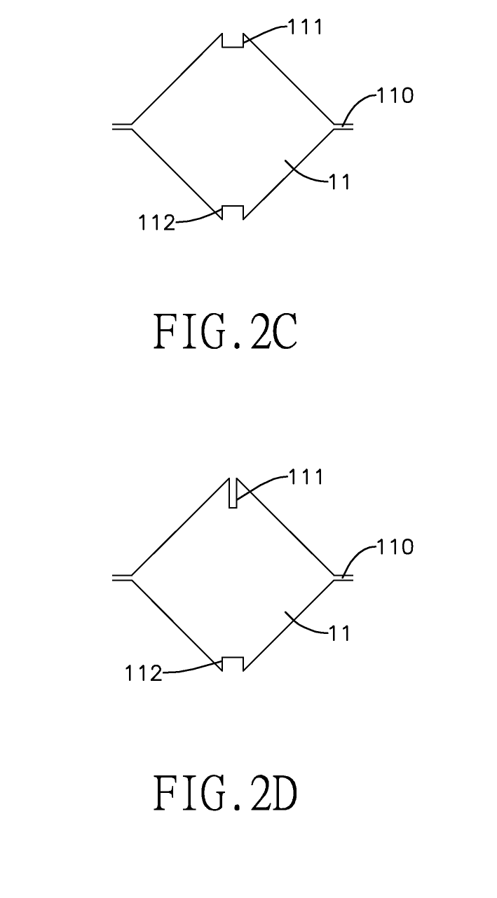

With reference to FIGS. 2A to 2D, the gaps 111, 112 are respectively formed at the top and bottom vertices of the X-axis electrode 11. As shown in FIG. 2A, a connecting portion 310 is formed between the two gaps 111,112 at a center of the X-axis electrode 11. The connecting portion has a height a and a width b. When the height a and the width b are equal, the resistance value is 1. As shown in FIG. 2B, the gaps 111, 112 of the X-axis electrode 11 are very narrow and slit-like. In the embodiment of the slits, left half and right half portions of the X-axis electrode 11 are respectively regarded as resistors R1, R2 connected in series. When the gaps 111, 112 of the X-axis electrode 11 are formed as slits, a capacitor is formed respectively between opposite edges of each gap 111, 112. The two capacitors are connected in parallel. The resistance value of the X-axis electrode 11 can be adjusted by modifying the shape of the gaps 111,112. As shown in FIG. 2D, the X-axis electrode 11 has two opposite gaps 111, 112 with different widths and depths.

With reference to FIG. 1, the Y-axis sensing layer has multiple Y-axis electrode strings 20. One end of each Y-axis electrode string 20 is respectively connected to a Y-axis driving line 201 formed on the substrate 300. Each Y-axis electrode string 20 is composed of multiple Y-axis electrodes 21 in series. At least one gap 211, 212 is formed on at least one Y-axis electrode 21 of at least one Y-axis electrode string 20. In this embodiment, the Y-axis sensing layer is the same as the X-axis sensing layer in that at least one gap 211, 212 is formed on all Y-axis electrodes 21 of all Y-axis electrode strings 20. In the embodiment, the Y-axis electrode 21 is in rhombic shape with a right vertex, a left vertex, a top vertex and a bottom vertex. The top and bottom vertices of the Y-axis electrode 21 are respectively connected to neighboring Y-axis electrodes 21 through a Y-axis connecting bridge 210. In the embodiment, the gaps 211, 212 are formed at the left and right vertices of the Y-axis electrode 21. The gaps 211, 212 of the Y-axis electrode 21 can be the same as the gaps 111, 112 of the X-axis electrode 11 in shape, position and size.

Because the X-axis electrode 11 and the Y-axis electrode 21 have the gaps 111, 112, 211, 212, the area covered by the electrode materials is reduced to lower the coupling capacitor between the X-axis electrode 11 and the Y-axis electrode 21.

All the X-axis electrodes 11 and all Y-axis electrodes 21 of the touch panel are formed with the gaps 111, 112, 211, 212 in the above embodiment. In another preferred embodiment, the gaps 111, 112, 211, 212 are formed on part of the X-axis electrodes 11 and Y-axis electrodes 21. The part of the X-axis electrodes 11 and Y-axis electrodes 21 are at locations relative far from the connecting port 310 on the substrate 300.

The resistance values of the X-axis electrode 11 and the Y-axis electrode 21 are adjustable by the previous gap structure. Further, the resistance values on the X-axis electrode and Y-axis electrode can be fine-tuned more precisely by the following structure.

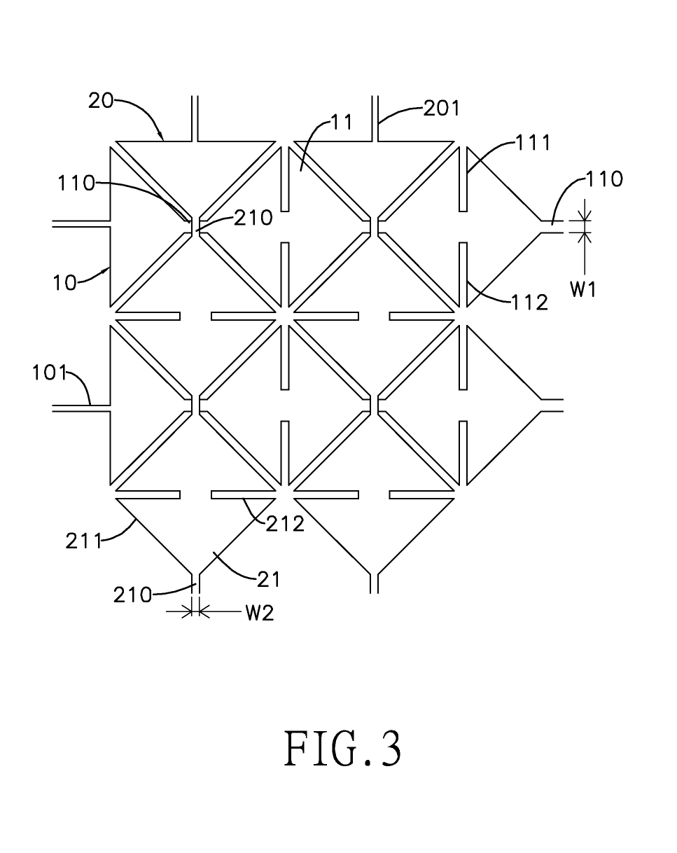

The neighboring X-axis electrodes 11 are connected by an X-axis connecting bridge 110. As shown in FIG. 3, the X-axis connecting bridge 110 has a first width (W1). The neighboring Y-axis electrodes 21 are connected by a Y-axis connecting bridge 210. The Y-axis connecting bridge 210 has a second width (W2). The second width (W2) is smaller than the first width (W1). In the embodiment, all of the X-axis connecting bridges 110 of all of the X-axis electrode strings 10 on the X-axis sensing layer have the same first width (W1). All of the Y-axis connecting bridges 210 of all of the Y-axis electrode strings 20 on the Y-axis sensing layer have the same second width (W2). The ratio of the first width (W1) to the second width (W2) depends on a ratio of the length to the width of the touch panel. For example, if the ratio of the length to the width of the touch panel is 16:9, the ratio of the first width (W1) to the second width (W2) can also be 16:9. The first width (W1) is 1.78 times to the second width (W2).

In more detail, the width of the Y-axis connecting bridge 210 on the Y-axis sensing layer maintains the original width (W2), while the width (W1) of the X-axis connecting bridge 110 on the X-axis sensing layer is enlarged to a desired value. The X-axis connecting bridge 110 is used as an electrically connecting structure between the neighboring X-axis electrodes 11 and also as a path for transmitting signals. The area and the resistance value of the X-axis connecting bridge 110 have an inverse relationship. When the width of the X-axis connecting bridge 110 between the neighboring X-axis electrodes is enlarged, the resistance value of X-axis connecting bridge 110 is reduced relatively. Therefore, the problem of the sensitivity being affected by the enlarged resistance value caused by the long driving line is solved, and the size of the touch panel can be enlarged.

For an X-axis electrode string 10, the width of the X-axis connecting bridges 110 on all the long X-axis electrodes can be enlarged. Furthermore, enlarging the width (W1) of the X-axis connecting bridges 110 of part of the X-axis electrode strings 10 is also practicable. This particular part of X-axis electrode strings 10 is formed at an area relative far from the connecting port 310. Because the part of X-axis electrode strings 10 is far away from the connecting port 310, the X-axis driving lines 101 connected to these X-axis electrode strings 10 have relative high resistance. However, the original high resistance of the X-axis electrode strings 10 can be fined-tuned by enlarging the X-axis connecting bridges 110.

Furthermore, the X-axis connecting bridges 110 of the X-axis sensing layer are respectively overlapped with and electrically isolated to the Y-axis connecting bridges 210 of the Y-axis sensing layer. When the area of the X-axis connecting bridge 110 and the area of the Y-axis connecting bridge 210 are large enough, a parasitic capacitor will occur between them. When the gap of the X-axis connecting bridge 110 is enlarged, the width of the Y-axis connecting bridge 210 is moderately reduced to avoid the parasitic capacitor on the premise of maintaining the sensitivity of the touch panel. For example, when the first width (W1) of the X-axis connecting bridge 110 is increased to 105%, the second width (W2) of the Y-axis connecting bridge 210 is decreased to 95%. The overlapped area between the X-, Y-axis connecting bridges 110, 210 is equivalent to the original state to effectively avoid the generating of the parasitic capacitor. In another example, when the first widths (W1) of the X-axis connecting bridge 110 are respectively increased to 110% or 115%, the second widths (W2) of the Y-axis connecting bridge 210 are respectively decreased to 90% or 85%.

From the above, the main objective of the invention is to reduce the area of all the electrodes or part of the electrodes at particular location on the touch panel to further reduce the impedance and accordingly enhance the sensitivity. Besides, the widths of the connecting bridge between the neighboring electrodes can further be adjusted to fine-tune the resistance of the electrodes. The resistance of the electrodes can be fine-tuned more precisely to further promote the sensitivity of the touch panel.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A projected capacitive touch panel with impedance adjustment structure comprising:
an X-axis sensing layer having
multiple X-axis electrode strings;
multiple X-axis driving lines, each of the X-axis driving lines connected to one end of one of the X-axis electrode strings, wherein the X-axis electrode strings comprise multiple X-axis electrodes connected in series; and
at least one first gap formed around at least one of the X-axis electrodes;
a Y-axis sensing layer having
multiple Y-axis electrode strings;
multiple Y-axis driving lines, each of the Y-axis driving lines connected to one end of one of the Y-axis electrode strings, wherein the Y-axis electrode strings comprise multiple Y-axis electrodes in series, wherein the Y-axis electrodes and the X-axis electrodes are arranged alternately; and
at least one second gap formed around at least one of the Y-axis electrodes.

2. The touch panel as claimed in claim 1, wherein the at least one X-axis electrode is in rhombic shape with a top vertex, a bottom vertex, a left vertex and a right vertex, wherein the right and left vertices of the X-axis electrodes are connected to the neighboring X-axis electrodes by X-axis connecting bridges, wherein the top and bottom vertices of at least one of the X-axis electrodes are formed with the first gaps respectively; and
each Y-axis electrode is in rhombic shape with a top vertex, a bottom vertex, a left vertex and a right vertex, wherein the top and bottom vertices' edges are connected to the neighboring Y-axis electrodes by Y-axis connecting bridges; wherein the left and right vertices of at least one of the Y-axis electrodes are formed with the second gaps respectively.

3. The touch panel as claimed in claim 2, wherein the first gaps are formed on all X-axis electrodes and the second gaps are formed on Y-axis electrodes.

4. The touch panel as claimed in claim 2, wherein the X-axis sensing layer and the Y-axis sensing layer are formed on a substrate; wherein at least one connecting port is formed on one side of the substrate and electrically connected to the X-axis driving lines and the Y-axis driving lines;
wherein the first gaps are formed on part of the X-axis electrodes far from the connecting port, and the second gaps are formed on part of the Y-axis electrodes far from the connecting port.

5. The touch panel as claimed in claim 2, wherein at least one of the X-axis connecting bridges has a first width, and at least one of the Y-axis connecting bridges has a second width smaller than the first width.

6. The touch panel as claimed in claim 3, wherein at least one of the X-axis connecting bridges has a first width, and at least one of the Y-axis connecting bridges has a second width smaller than the first width.

7. The touch panel as claimed in claim 4, wherein at least one of the X-axis connecting bridges has a first width, and at least one of the Y-axis connecting bridges has a second width smaller than the first width.

8. The touch panel as claimed in claim 5, wherein a ratio of the first width to the second width is 16:9.

9. The touch panel as claimed in claim 6, wherein a ratio of the first width to the second width is 16:9.

10. The touch panel as claimed in claim 7, wherein a ratio of the first width to the second width is 16:9.

11. The touch panel as claimed in claim 5, wherein the first width is increased to 105% and the second width is decreased to 95%.

12. The touch panel as claimed in claim 6, wherein the first width is increased to 105% and the second width is decreased to 95%.

13. The touch panel as claimed in claim 7, wherein the first width is increased to 105% and the second width is decreased to 95%.

14. The touch panel as claimed in claim 5, wherein the first width is increased to 110% and the second width is decreased to 90%.

15. The touch panel as claimed in claim 6, wherein the first width is increased to 110% and the second width is decreased to 90%.

16. The touch panel as claimed in claim 7, wherein the first width is increased to 110% and the second width is decreased to 90%.

17. The touch panel as claimed in claim 5, wherein the first width is increased to 115% and the second width is decreased to 85%.

18. The touch panel as claimed in claim 6, wherein the first width is increased to 115% and the second width is decreased to 85%.

19. The touch panel as claimed in claim 7, wherein the first width is increased to 115% and the second width is decreased to 85%.
